(19) United States
(12) Patent Application Publication
(10) Pub. No.: US 2025/0338559 A1
(43) Pub. Date: Oct. 30, 2025

(54) DUAL SILICIDE CONTACTS ENABLED WITH ION IMPLANTATION

(71) Applicant: ENTEGRIS, INC., Billerica, MA (US)

(72) Inventors: Paul Raymond Besser, Sunnyvale, CA (US); Kaitlin Jeanne Lawrence, Brookfield, CT (US); Jun-Fei Zheng, Westport, CT (US)

(21) Appl. No.: 19/189,053

(22) Filed: Apr. 24, 2025

Related U.S. Application Data
(60) Provisional application No. 63/638,524, filed on Apr. 25, 2024.

(51) Int. Cl. H10D 30/67; H10D 30/01; H10D 64/01; H10D 64/27; H10D 80/20

(52) U.S. Cl. CPC H10D 30/6735; H10D 30/0321; H10D 64/01; H10D 64/529; H10D 80/251

(57) ABSTRACT

The disclosure provides a method for fabricating a low resistance contact on a semiconductor substrate comprising a metal oxide semiconductor (MOS) device. The method comprises fabricating a via to a source or drain region of the MOS device, providing an insulating layer along a sidewall of the via while maintaining or reestablishing the exposed source or drain region, using ion implantation to implant a metallic element into the exposed source or drain region of the semiconductor substrate through the via to form an implanted layer, annealing the implanted layer to form a silicide layer comprising silicon and the metallic element on the source or drain region of the MOS device, and depositing a low resistance metal in the via to form the low resistance contact on the semiconductor substrate comprising the MOS device. The disclosure also provides a device comprising a low resistance contact fabricated by said method.

### CROSS-REFERENCE TO RELATED APPLICATION

This application claims the benefit of and priority to U.S. Provisional Application No. 63/638,524, filed on Apr. 25, 2024, the contents of which are incorporated by reference herein in their entirety for all purposes.

### TECHNICAL FIELD

This disclosure generally relates to fabrication of low resistance contacts in metal oxide semiconductor devices.

### BACKGROUND

Ensuring optimal device performance and functionality relies heavily on creating low resistance contacts on semiconductor substrates. This process typically entails depositing metal and inducing reactions at elevated temperatures. However, challenges arise at different stages of the complementary metal-oxide-semiconductor (CMOS) process flow, where various factors can impact the conditions for fabricating specific contacts, hindering efforts to achieve low resistance. For example, during the backside process, constraints on the thermal budget aim to prevent damage to the circuitry already established by the frontside process.

### SUMMARY

The disclosure provides a method for fabricating a low resistance contact on a semiconductor substrate comprising a metal oxide semiconductor (M OS) device, the method comprising: fabricating a via to a source or drain region of the MOS device, wherein the source or drain region comprises silicon, to expose the source or drain region; providing an insulating layer along a sidewall of the via while maintaining or reestablishing the exposed source or drain region; using ion implantation to implant a metallic element into the exposed source or drain region of the semiconductor substrate through the via to form an implanted layer, wherein the metallic element is erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof; annealing the implanted layer to form a silicide layer comprising silicon and the metallic element on the source or drain region of the MOS device; and depositing a low resistance metal in the via to form the low resistance contact on the semiconductor substrate comprising the MOS device.

The disclosure further provides a device comprising a low resistance contact fabricated by the method provided in the present disclosure.

The disclosure further provides a semiconductor device, comprising: a metal oxide semiconductor (MOS) comprising source and drain regions; vias extending to the source and drain regions of the MOS, wherein the vias have sidewalls covered by an insulating layer; silicide layers comprising silicon and a metallic element selected from erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof on the source and drain regions of the MOS device; and a low resistance metal on the silicide layers and filling in the vias.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a diagram of an example field-effect transistor (FET), in accordance with one or more embodiments of the present disclosure.

FIG. 2 is a process flow illustrating the current state-of-art process for fabricating a metal contact on a semiconductor substrate.

FIG. 3 is a schematic of an exemplary MOS device with backside contacts, in accordance with one or more embodiments of the present disclosure.

FIG. 4 is an exemplary process flow for fabricating dual-silicide contacts on MOS devices on a semiconductor substrate, in accordance with one or more embodiments of the present disclosure.

### DETAILED DESCRIPTION

There is an ongoing need to develop new processes that facilitate the fabrication of low resistance contacts while remaining compatible with the existing CMOS process flow. The present disclosure provides materials and methods to facilitate such processes. These and other advantages of the present disclosure, as well as additional inventive features, will be apparent from the description of the present disclosure provided herein.

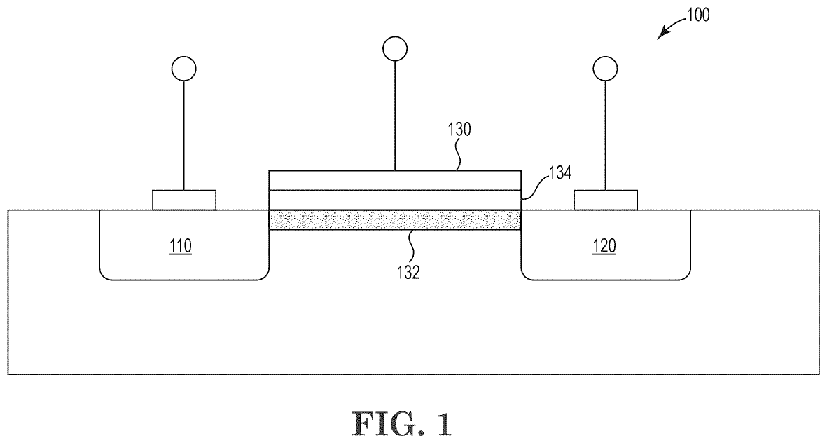

FIG. 1 is a schematic of an example field-effect transistor (FET) 100, in accordance with one or more embodiments of the present disclosure. As depicted in FIG. 1, a FET 100 includes various components, including a source region 110, a drain region 120, and a gate region 130. The source region 110 is the terminal through which current enters the channel region of the FET when the FET is in the “on” state. The source region 110 is typically heavily doped to ensure efficient current injection. The drain region 120 is the terminal through which current exits the channel region of the FET when it is in the “on” state. The drain region 120 is also heavily doped to facilitate the collection of charge carriers. The gate region 130 is the terminal that controls the conductivity of a channel region 132 between the source 110 and drain 120. The gate region 130 is separated from the channel by a thin insulating layer 134. The insulating layer 134 is usually made of a dielectric material (e.g., silicon dioxide (SiO₂)), while the gate region 130 is typically made of a conductive material such as polysilicon or metal (e.g., titanium or tungsten).

Metal-oxide-semiconductor field-effect transistor (MOSFET) is a specific type of FET. MOSFET has a metal gate insulated from the semiconductor by a thin layer of oxide (e.g., silicon dioxide). Other types of FETs include junction field-effect transistors (JFETs) and metal-semiconductor field-effect transistors (MESFETs).

N- and P-FETs are semiconductor devices that utilize different types of charge carriers. The different types of charge carriers are related to different types of doping in the semiconductor devices. For example, a semiconductor substrate doped with acceptor impurities is referred to as a p-type doping, which may result in a surplus of “holes” as majority carriers. A semiconductor substrate doped with donor impurities is referred to as an n-type doping, which may result in a surplus of “electrons” as majority carriers.

In a NFET, the source and drain regions are typically doped with n-type impurities (e.g., donor impurities), while the semiconductor substrate is typically doped with acceptor impurities. This creates a P-N junction between the source/drain region and the semiconductor substrate. A voltage applied to the gate terminal relative to the source controls the “on” and “off” states of the NFET. For example, a positive gate voltage repels the holes out of the substrate beneath the gate region and attracts electrons to that region. With sufficient positive gate voltage, an n-type conductive channel forms in the substrate below the gate region, allowing electrons to flow between the source and drain regions. In this case, the NFET is “on.” Without the formation of a conductive channel between the source and drain regions, the NFET is “off.”

In a PFET, the source and drain regions are typically doped with p-type impurities, while the semiconductor substrate is typically doped with donor impurities. Similar to the NFET, this creates a P-N junction between the source/drain region and the semiconductor substrate. Similarly, a voltage applied to the gate terminal relative to the source controls the “on” and “off”' states of the PFET. For example, a negative gate voltage repels the electrons out of the substrate beneath the gate region and attracts holes to that region. With sufficient negative gate voltage, a p-type conductive channel forms in the substrate below the gate region, allowing the holes to flow between the source and drain regions. In this case, the PFET is “on.” Without the formation of a conductive channel between the source and drain regions, the PFET is “off.”

Work function refers to the minimum energy required to remove an electron from a material's surface to a point just outside the material. It is a fundamental property of materials and is typically measured in electron volts (eV). In semiconductor devices, work function is utilized to determine the energy barrier at the interface between different materials, such as metal contacts and semiconductor substrates. It affects electron transport across these interfaces and influences device performance, particularly in MOS devices with metal-semiconductor contacts.

Fabricating contacts on the source and drain regions typically involves depositing a conductive material, such as a metal, onto the doped semiconductor substrate, followed by a subsequent thermal annealing process to form a metallic silicide contact with low resistivity. Reactions between the thin metal layer and the semiconductor substrate occur at elevated temperatures, which may lead to dopant deactivation and can introduce interface states, trap charges, and other defects, further impacting device characteristics such as carrier mobility, posing challenges in achieving optimal device performance.

The present disclosure provides methods and materials for fabricating a low resistance contact on a semiconductor substrate by forming a silicide layer comprising silicon and one or more specific metallic elements. The silicide layer acts as an interfacial layer between the contact metal and the semiconductor substrate. The metallic elements are selected based on the type of semiconductor substrate being used, and these metallic elements are incorporated into chemical compositions compatible with the ion implantation process. A silicide to silicon interface is more stable than a metal to silicon interface. Additionally, silicides form a Schottky diode with silicon. Schottky diodes are the preferred rectifier for low voltage, high current applications.

By forming the silicide layer between the contact metal and the semiconductor substrate, the resulting contact may have a modified work function for optimized device performance. For example, in a PMOS device, the work function of the resulting contact may be higher than the work function of the p-type semiconductor material, allowing holes to efficiently flow across the metal-semiconductor interface. Conversely, in an NM OS device, the work function of the resulting contact may be lower than that of the n-type semiconductor material to facilitate efficient electron transport.

Furthermore, the utilization of the ion implantation process, in conjunction with the selection of specific chemical compositions, offers some benefits. For example, the ion implantation process may enable the formation of the silicide layer at lower thermal budgets. This allows the methods provided in the present disclosure to be compatible with various stages of the semiconductor production process. For example, backside processing may require the temperature to be below 430° C. (e.g., below 420° C., below 410° C., or below 400° C. such as, for example, 300° C. to 430° C., 300° C. to 420° C., 300° C. to 410° C., 300° C. to 400°° C., 350° C. to 430° C., 350° C. to 420° C., 350° C. to 410° C., 350° C. to 400° C., 400° C. to 430° C., 400° C. to 420° C., or 400° C. to 410° C.), while frontside processing may reach temperatures up to 450° C. (e.g., 300° C. to 450° C., 350° C. to 450° C., 400° C. to 450° C., or 430° C. to 450° C.) and potentially above 450° C. (e.g., above 460° C., above 480° C., or above 500° C. such as, for example, 450° C. to 460° C., 450° C. to 480° C., 450° C. to 500° C., 450° C. to 550° C., or 450° C. to 600° C.). Additionally, ion implantation facilitates the directional injection of ions, ensuring that the majority of ions are implanted into the target surface with only negligible amount on untargeted surfaces (e.g., sidewalls).

As discussed above, the present disclosure enables low contact resistance formation at low thermal budget with ion implantation of materials, resulting in a thin metal silicide selectively formed at low temperature, tailored to N and P devices.

The low contact resistance silicide formation is achieved with ion implantation of materials that lower the contact resistance and reduces the anneal temperature. The implanted metal may be tailored to N and P and amorphize the epitaxial silicon, enabling formation of low resistance (Rs) contacts at scaled dimensions and the low thermal budget associated with backside contacts (BSC). The use of ion implantation enables materials to be incorporated at room temperature.

Furthermore, as mentioned earlier, ion implantation has high directionality. The implanted material may form silicide only in the contact area of source/drain with negligible amount on the sidewall of the via, thus creating a nearly selectively placement of the desired metal on the silicon for formation of silicide in the desired area only. By contrast, normally contact metal would be conformally deposited on side walls, as well as contact bottom. By implementing the methods disclosed herein, the silicide may enable electronic work function (EWF) modulation for dual silicides.

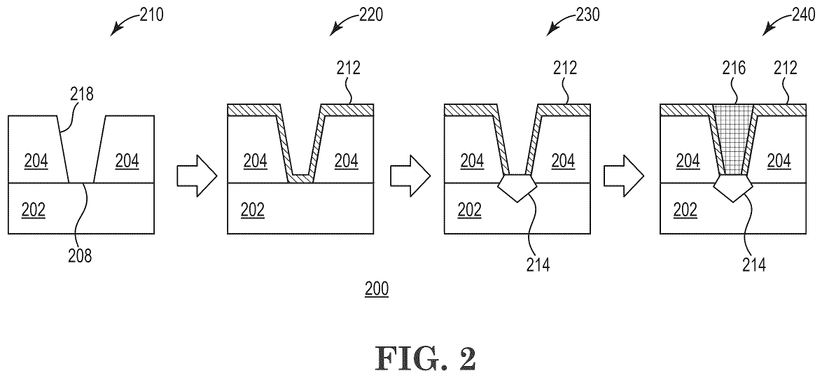

FIG. 2 is a process flow 200 illustrating the current state-of-art process for fabricating a metal contact on a semiconductor substrate.

At 210, a contact is to be formed on a silicon substrate 202. An interlayer dielectric (ILD) 204 is fabricated on the silicon substrate 202. The ILD 204 is patterned to expose a target region 208 for contact fabrication. The ILD 204 is often used for insulation between metal layers or conductive structures in semiconductor fabrication. For example, a vertical via 218 (e.g., a trench or channel) may be made in the ILD 204 to expose the target region 208 on the silicon substrate 202. Vias may vary in width and depth depending on the specific design requirements and fabrication process parameter.

At 220, a conformal layer 212 is fabricated on the patterned substrate, covering the ILD 204 and the exposed region 208 of the silicon substrate 202. This metal layer is typically a bilayer consisting of a metal and a highly resistive metal nitride.

At 230, the deposited metal in layer 212 may react with silicon in the silicon substrate 202 during a subsequent annealing process, forming an interfacial layer (214) that facilitates the formation of a contact with low resistance. The interfacial layer may include silicide formed based on the deposited metal(s) and the silicon substrate 202. The metal nitride protects the metal from oxidation during the annealing process.

At 240, additional metal is deposited to fill the contact region 216 (e.g., in the via 218) defined by the pattern of the ILD layer 204. For example, the metal deposited in this process may be tungsten (W).

The deposition of the metal(s) on the Si substrate (e.g., at 220) is typically performed using Physical Vapor Deposition (PVD), Chemical Vapor Deposition (CVD), or Atomic Layer Deposition (ALD). Following step 240, the device is typically annealed at elevated temperatures to ensure sufficient reactions between the deposited metal(s) and the silicon.

However, the current process flow (e.g., the process flow 200) encounters several challenges when implemented in semiconductor device fabrication, particularly concerning the growing demand for scaling.

For example, this process flow may lead to issues with via resistance, as unreacted metal and metal nitride left on the sidewall is highly resistive. In some cases, the thickness of unreacted metal may be reduced with CVD or ALD deposition. However, many suitable metals for N and P silicide formation are difficult to deposit (as pure metal) by ALD or CVD, since precursors are often not available. Conventionally, high deposition temperature is required or excess process conditions (such as plasma) are necessitated. In other words, the current process poses particular challenges when a limited thermal budget is in place.

In the present disclosure, a metallic element is implanted into a specific region of a semiconductor substrate to form an implanted layer. The metallic element is erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof. The implanted layer is annealed to form a silicide layer comprising silicon and the metallic element in the respective region of the semiconductor substrate. A low resistance metal (e.g., titanium, tungsten, molybdenum, ruthenium, cobalt, nickel, or a combination thereof) is deposited on the silicide layer to form a low resistance contact on the semiconductor substrate. This allows the low resistance contact to be formed while adhering to varying thermal budgets associated with different stages of semiconductor device fabrication. Additionally, “selective” material addition is achieved by forming silicide solely in the target area (e.g., the contact area of source/drain), thereby improving device performance.

In some embodiments, the semiconductor substrate may be silicon (or doped silicon), silicon germanium (SiGe), silicon carbide (SiC), or other suitable semiconductor substrate.

In some embodiments, the method comprises fabricating a via to a source or drain region of an N-channel metal-oxide semiconductor, wherein the source or drain region comprises silicon, to expose the source or drain region. The metallic element used for ion implantation of the source or drain region of the N-channel metal-oxide semiconductor can be erbium (Er), ytterbium (Yb), dysprosium (Dy), gadolinium (Gd), scandium (Sc), hafnium (Hf), zirconium (Zr), molybdenum (Mo), or a combination thereof. Thus, in some embodiments, the silicide layer of the N-channel metal-oxide semiconductor comprises silicon and erbium (Er), ytterbium (Yb), dysprosium (Dy), gadolinium (Gd), scandium (Sc), hafnium (Hf), zirconium (Zr), molybdenum (Mo), or a combination thereof. In some embodiments, the silicide layer of the N-channel metal-oxide semiconductor has a work function from about 0.55 eV to about 0.2 eV (e.g., about 0.5 eV to about 0.2 eV, about 0.45 eV to about 0.2 eV, about 0.4 eV to about 0.2 eV, about 0.35 eV to about 0.2 eV, about 0.3 eV to about 0.2 eV, about 0.55 eV to about 0.25 eV, about 0.5 eV to about 0.25 eV, about 0.45 eV to about 0.25 eV, about 0.4 eV to about 0.25 eV, about 0.35 eV to about 0.25 eV, about 0.3 eV to about 0.25 eV, about 0.55 eV to about 0.3 eV, about 0.5 eV to about 0.3 eV, about 0.45 eV to about 0.3 eV, about 0.4 eV to about 0.3 eV, or about 0.35 eV to about 0.3 eV).

The metallic element used for ion implantation of the N-type semiconductor substrate can be derived from any suitable source material. In some embodiments, the metallic element used for ion implantation of the N-type semiconductor substrate is erbium (Er), ytterbium (Yb), dysprosium (Dy), or gadolinium (Gd) and the ion implantation utilizes a volatile mixture of aluminum chloride and erbium (Er) chloride, ytterbium (Yb) chloride, dysprosium (Dy) chloride, or gadolinium (Gd) chloride as a source to implant the metallic element. In other embodiments, the metallic element used for ion implantation of the N-type semiconductor substrate is hafnium (Hf), zirconium (Zr), or molybdenum (Mo) and the ion implantation utilizes hafnium tetrachloride, zirconium borohydride, zirconium tetrafluoride, molybdenum chloride, molybdenum pentafluoride, molybdenum hexafluoride, molybdenum oxytetrafluoride, or molybdenum hexacarbonyl as a source to implant the metallic element.

In some embodiments, the method comprises fabricating a via to a source or drain region of a P-channel metal-oxide semiconductor, wherein the source or drain region comprises silicon, to expose the source or drain region. The metallic element used for ion implantation of the source or drain region of the P-channel metal-oxide semiconductor can be iridium (Ir), platinum (Pt), osmium (Os), ruthenium (Ru), palladium (Pd), rhenium (Re), rhodium (Rh), or a combination thereof. Thus, in some embodiments, the silicide layer of the P-channel metal-oxide semiconductor comprises silicon and iridium (Ir), platinum (Pt), osmium (Os), ruthenium (Ru), palladium (Pd), rhenium (Re), rhodium (Rh), or a combination thereof. In some embodiments, the silicide layer of the P-channel metal-oxide semiconductor has a work function from about 0.7 eV to about 0.95 eV (e.g., about 0.7 eV to about 0.9 eV, about 0.7 eV to about 0.85 eV, about 0.7 eV to about 0.8 eV, about 0.7 eV to about 0.75 eV, about 0.75 eV to about 0.95 eV, about 0.75 eV to about 0.9 eV, about 0.75 eV to about 0.85 eV, about 0.75 eV to about 0.8 eV, about 0.8 eV to about 0.95 eV, about 0.8 eV to about 0.9 eV, about 0.8 eV to about 0.85 eV, about 0.85 eV to about 0.95 eV, about 0.85 eV to about 0.9 eV, or about 0.9 eV to about 0.95 eV).

The metallic element used for ion implantation of the P-type semiconductor substrate can be derived from any suitable source material. In some embodiments, the metallic element used for ion implantation of the P-type semiconductor substrate is iridium (Ir), platinum (Pt), osmium (Os), ruthenium (Ru), or rhenium (Re) and the ion implantation utilizes iridium hexafluoride, tetrakis(trifluorophosphine)platinum, osmium tetroxide, osmium carbonyl, osmium pentafluoride, osmium hexafluoride, ruthenium hexafluoride, ruthenium pentafluoride, ruthenium carbonyl, ruthenium tetroxide, rhenium pentafluoride oxide, rhenium pentafluoride, rhenium hexafluoride, or rhenium heptafluoride as a source to implant the metallic element.

In some embodiments, the metallic element(s) is provided in a volatile implantation precursor (i.e., a source for implantation). In some scenarios, volatile implantation precursors with high thermal stability and low carbon content may be used. As used herein, “volatile implantation precursors” refer to compounds with a vapor pressure (Pᵥₐₚ) greater than 10 torr at a temperature between 25° C. and 200° C. In some embodiments, gaseous precursors are utilized, which are flowed directly into arc chamber from a gas source. The gas source may be either pure gas source, co-flowed, or mixed with hydrogen and other hydrides to prevent reaction with filament and increase beam current. In some embodiments, sputtering precursors are employed. sputtering precursors may be obtained by placing solids into arc chamber, sputtering the solids into ions using a gaseous precursors, and heating to volatilize species for implant.

The source to implant the metallic element can be generated by any suitable method. In some embodiments, the source to implant the metallic element is generated by exposing the metallic element or an oxide thereof to a fluorinating vapor (e.g., F₂, PF₂, etc.) or a chlorinating agent (Cl₂, PCl₂, etc.).

In some embodiments, a step of pre-amorphization implantation (PAI) may be utilized. For example, in some embodiments, a step of pre-amorphization implantation (PAI) may be performed for the source or drain region prior to using ion implantation to implant a metallic element into the exposed source or drain region of the semiconductor substrate. In PAI, high-energy ion implantation is employed to amorphize a thin surface layer of the semiconductor material (e.g., silicon). PAI enables the formation of low resistance silicide at a reduced anneal temperature. Silicide may form at a lower temperature when silicon is amorphous by ion implantation. The material used for pre-amorphization implantation may include silicon (Si), germanium (Ge), xenon (Xe), carbon (C), and arsenic (As), or other suitable material. The pre-amorphization implantation may be performed for the source or drain region prior to using ion implantation to implant a metallic element into the exposed source or drain region of the semiconductor substrate. In certain embodiments, the method comprises a step of pre-amorphization implantation of the source or drain region with silicon (Si) or germanium (Ge) prior to using ion implantation to implant a metallic element into the exposed source or drain region of the semiconductor substrate.

The ion implantation process, coupled with the selected metallic elements mentioned earlier, may be utilized to fabricate metal oxide semiconductor (MOS) devices with low contact resistance.

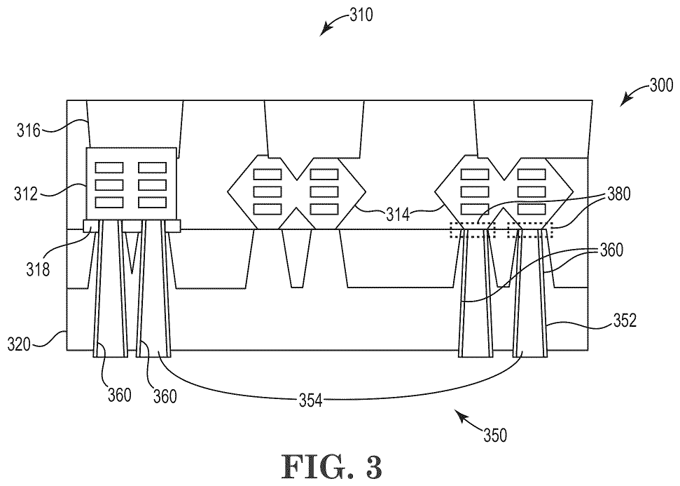

FIG. 3 is a schematic of an exemplary MOS device 300 with backside contacts, in accordance with one or more embodiments of the present disclosure. The MOS device 300 may be one of a plurality of MOS devices fabricated on a wafer substrate, such as the silicon substrate 320. The silicon substrate 320 has an upper side 310, referred to as the frontside, and a bottom side 350, referred to as the backside.

The plurality of MOS devices (e.g., the MOS device 300) are fabricated on the frontside 310 of the silicon substrate 320. The MOS device 300 includes a metal gate region 312 and a source and drain region 314. In this example, the gate is a gate-all-around (GAA) gate, and the source and drain include an epitaxial layer (314) grown on the source and drain regions. Contacts 316 are made on the source, drain, and gate of the MOS device 300, enabling their connections to an interconnect network (e.g., a frontside power delivery network). A bottom dielectric insulating (BDI) layer 318 is deposited on the silicon substrate 320, providing electrical isolation between the different transistor components and other structures fabricated on the silicon surface.

At the backside 350, backside contacts 354 are made through the silicon substrate 320. For example, in the backside contact regions (e.g., for contacts 354), vias 360 are created to reach the bottom surface of the source, drain, and gate of the MOS device 300. Subsequently, a dielectric insulator 352 is deposited on the sidewalls of the vias 360, and a contact material (e.g., metal) is filled in the vias 360 to establish electrical connections.

In this example, the ion implantation and the selected metallic element(s) may be applied to regions 380 of the MOS device 300 to form a corresponding silicide layer in these regions. For example, after exposing the bottom surface of the source/drain of the M OS device 300 and fabricating the dielectric insulator 352, the selected metallic element(s) may be implanted into the respective source/drain region in 380 using ion implantation. The corresponding silicide layer may be formed after an annealing process.

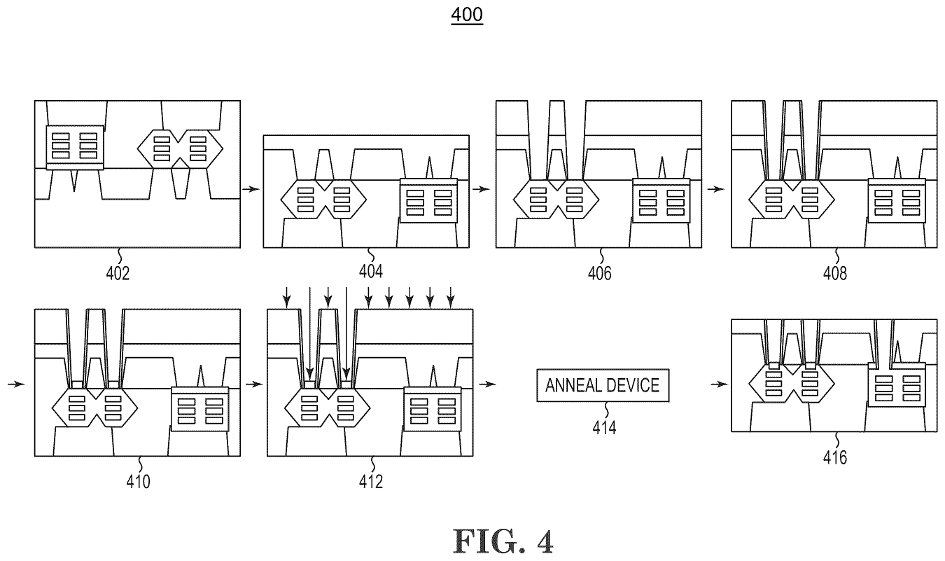

In some embodiments, dual-silicide contacts may be formed on a semiconductor substrate comprising PMOS and NMOS devices. Separate ion implantation processes may be performed to form N-type silicide and P-type silicide, respectively. As such, the disclosure provides a method for fabricating a low resistance contact on a semiconductor substrate comprising a metal oxide semiconductor (MOS) device comprising: (i) fabricating a via to a source or drain region of the MOS device, wherein the source or drain region comprises silicon, to expose the source or drain region (see, for example, FIG. 4 at 406), (ii) providing an insulating layer along a sidewall of the via while maintaining or reestablishing the exposed source or drain region (see, for example, FIG. 4 at 408), (iii) using ion implantation to implant a metallic element into the exposed source or drain region of the semiconductor substrate through the via to form an implanted layer, wherein the metallic element is erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof (see, for example. FIG. 4 at 412), (iv) annealing the implanted layer to form a silicide layer comprising silicon and the metallic element on the source or drain region of the MOS device, and (v) depositing a low resistance metal in the via to form the low resistance contact on the semiconductor substrate comprising the MOS device (see, for example, FIG. 4 at 416).

The implanted layer can be annealed at any suitable temperature to form a silicide layer comprising silicon and the metallic element on the source or drain region of the MOS device. For example, the implanted layer can be annealed by exposing the semiconductor substrate to a temperature of 430° C. or lower (e.g., 420° C. or lower, 410° C. or lower, or 400° C. or lower such as, for example, 300° C. to 430° C., 300° C. to 420° C., 300° C. to 410° C., 300° C. to 400° C., 350° C. to 430° C., 350° C. to 420° C., 350° C. to 410° C., 350° C. to 400° C., 400° C. to 430° C., 400° C. to 420° C., or 400° C. to 410° C.), the implanted layer can be annealed by exposing the semiconductor substrate to a temperature of 430° C. to 450° C. (e.g., 430° C. to 440° C. or 440° C. to 450° C.), or the implanted layer can be annealed by exposing the semiconductor substrate to a temperature of 450° C. to 500° C. (e.g., 450° C. to 490° C., 450° C. to 480° C., 450° C. to 470° C., 450° C. to 460° C., 460° C. to 500° C., 460° C. to 490° C., 460° C. to 480° C., 460° C. to 470° C., 470° C. to 500° C., 470° C. to 490° C., or 470° C. to 480° C.).

The method comprises fabricating a via to a source or drain region of the MOS device, wherein the source or drain region comprises silicon, to expose the source or drain region. In some embodiments, the method comprises fabricating vias to source and drain regions comprising silicon of an N-channel metal-oxide semiconductor to expose the source and drain regions. In other embodiments, the method comprises fabricating vias to source and drain regions comprising silicon of a P-channel metal-oxide semiconductor to expose the source and drain regions. In certain embodiments, the method comprises fabricating vias to source and drain regions comprising silicon of an N-channel metal-oxide semiconductor to expose the source and drain regions and fabricating vias to source and drain regions comprising silicon of a P-channel metal-oxide semiconductor to expose the source and drain regions.

In embodiments where the method comprises fabricating vias to source and drain regions comprising silicon of an N-channel metal-oxide semiconductor to expose the source and drain regions, the method may further comprise masking the source and drain regions of the P-channel metal-oxide semiconductor and selectively implanting erbium (Er), ytterbium (Yb), dysprosium (Dy), gadolinium (Gd), scandium (Sc), hafnium (Hf), zirconium (Zr), molybdenum (Mo), or a combination thereof into the exposed source and drain regions of the N-channel metal-oxide semiconductor. Alternatively, or additionally, in embodiments, where the method comprises fabricating vias to source and drain regions comprising silicon of a P-channel metal-oxide semiconductor to expose the source and drain regions, the method may further comprise masking the source and drain regions of the N-channel metal-oxide semiconductor and selectively implanting iridium (Ir), platinum (Pt), osmium (Os), ruthenium (Ru), palladium (Pd), rhenium (Re), rhodium (Rh), or a combination thereof into the exposed source and drain regions of the P-channel metal-oxide semiconductor.

In some embodiments, the method comprises forming a dual silicide where the N-channel metal-oxide semiconductor comprises a first silicide layer comprising silicon and erbium (Er), ytterbium (Yb), dysprosium (Dy), gadolinium (Gd), scandium (Sc), hafnium (Hf), zirconium (Zr), molybdenum (Mo), or a combination thereof on the source and drain regions of the N-channel metal-oxide semiconductor and the P-channel metal-oxide semiconductor comprises a second silicide layer comprising silicon and iridium (Ir), platinum (Pt), osmium (Os), ruthenium (Ru), palladium (Pd), rhenium (Re), rhodium (Rh), or a combination thereof on the source and drain regions of the P-channel metal-oxide semiconductor.

In some embodiments, the method further comprises growing epitaxial silicon in the source or drain region of the semiconductor substrate prior to the ion implantation of the metallic element, wherein the step of using ion implantation to implant a metallic element into the exposed source or drain region of the semiconductor substrate comprises using ion implantation to implant a metallic element into the epitaxial silicon grown in the source or drain region of the semiconductor substrate to form an implanted layer comprising the epitaxial silicon and the implanted metallic element.

The method for fabricating a low resistance contact can be utilized to fabricate a low resistance contact on the backside power delivery network of the semiconductor substrate and/or the frontside power delivery network of the semiconductor substrate. In some embodiments, the low resistance contact is fabricated on a backside power delivery network of the semiconductor substrate. In other embodiments, the low resistance contact is fabricated on a frontside power delivery network of the semiconductor substrate.

The method comprises depositing a low resistance metal in the via to form the low resistance contact on the semiconductor substrate comprising the MOS device. The low resistance metal can be any suitable metal. In some embodiments, the low resistance metal comprises titanium, tungsten, molybdenum, ruthenium, cobalt, aluminum, nickel, or a combination thereof. In certain embodiments, the method further comprises chemical-mechanical polishing of the low resistance metal to planarize the low resistance metal.

In some embodiments, the method for fabricating a low resistance contact on a semiconductor substrate further comprises one or more subsequent processes. For example, the method for fabricating a low resistance contact on a semiconductor substrate may further involve chemical-mechanical polishing (CMP) and/or the fabrication of copper dual-damascene (CuDD) interconnects. This enables the creation of a backside power delivery network. For example, chemical-mechanical polishing of the low resistance metal may be utilized to planarize the low resistance metal.

The disclosure further provides a device comprising a low resistance contact fabricated by the method described herein. For example, the disclosure further provides a semiconductor device, comprising: a metal oxide semiconductor (MOS) comprising source and drain regions; vias extending to the source and drain regions of the MOS, wherein the vias have sidewalls covered by an insulating layer; silicide layers comprising silicon and a metallic element selected from erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof on the source and drain regions of the MOS device; and a low resistance metal on the silicide layers and filling in the vias.

In some embodiments, a semiconductor device comprises dual silicide contacts enabled by the ion implantation method described herein. For example, the semiconductor device can comprise (i) an N-channel metal-oxide semiconductor comprising source and drain regions; a first set of vias extending to the source and drain regions of the N-channel metal-oxide semiconductor, wherein the first set of vias have sidewalls covered by a first insulating layer; a first set of silicide layers comprising silicon and a metallic element selected from erbium (Er), ytterbium (Yb), dysprosium (Dy), gadolinium (Gd), scandium (Sc), hafnium (Hf), zirconium (Zr), molybdenum (Mo), or a combination thereof on the source and drain regions of the N-channel metal-oxide semiconductor; and a first low resistance metal on the first set of silicide layers and filling in the first set of vias, and (ii) a P-channel metal-oxide semiconductor comprising source and drain regions; a second set of vias extending to a surface of the source and drain regions of the P-channel metal-oxide semiconductor, wherein the second set of vias have sidewalls covered by a second insulating layer; a second set of silicide layers comprising silicon and a metallic element selected from iridium (Ir), platinum (Pt), osmium (Os), ruthenium (Ru), palladium (Pd), rhenium (Re), rhodium (Rh), or a combination thereof on the source and drain regions of the P-channel metal-oxide semiconductor; and a second low resistance metal on the second set of silicide layers and filling in the second set of vias.

### EXAMPLES

These following examples further illustrate the disclosure but, of course, should not be construed as in any way limiting its scope.

### Example 1

This example shows an exemplary process for forming dual-silicide contacts on a semiconductor substrate comprising PMOS and NMOS devices with reference to FIG. 4. FIG. 4 is an exemplary process flow 400 for fabricating dual-silicide contacts on MOS devices on a semiconductor substrate, in accordance with one or more embodiments of the present disclosure. The process flow 400 may be applied to wafer level processing, where the corresponding processes are performed on semiconductor devices (e.g., MOS devices) on a wafer substrate (e.g., the silicon (Si) substrate). It will be noted that part or all of the processes in the process flow 400 may be performed to fabricate devices with low resistance contacts. Additionally, the processes described herein can be performed in any suitable order. In this example, the semiconductor devices includes NMOS and PMOS devices.

At 402, a wafer is provided at the end of front-end of the line (FEOL) processing and/or back-end of line (BEOL) processing. In wafer manufacturing, the FEOL processing leads to transistor formation, whereas the BEOL processing results in interconnect formation.

At 404, the wafer is flipped. The silicon substrate is thinned.

At 406, contact layers, such as the surfaces of the source/drain regions, are exposed by employing photolithography and etching processes. For example, a hard mask is patterned based on the desired regions to expose using photolithography, and then the underlying Si substrate is etched according to the patterns defined by the hard mask. This process creates vias (or channels/trenches) in the substrate, exposing the desired regions, such as the source/drain surfaces. In some scenarios, the diameter of the vias may be as small as 15 nanometers.

At 408, an insulating layer, such as an oxide liner, is deposited on the surfaces exposed by the etch process, such as the sidewalls of the created vias, and the source/drain surfaces. The insulating layer on the source/drain surfaces is removed (e.g., etched away) to reestablishing the exposed source/drain surfaces.

At 410, as an optional step, selective epitaxial (or Epi) silicon (or doped silicon) may be grown on the active area of the source/drain, such as the exposed source/drain surfaces. This Epi layer may reduce the consumption of the silicon in the silicon substrate when forming the silicide layer. This step may require two steps to form P- and N-type Epi layers independently.

At 412, the NMOS device(s) on the Si substrate is masked and ion implantation is performed on the PMOS device(s).

At 414, the PMOS device(s) on the Si substrate is masked and ion implantation is performed on the NMOS device(s). It will be noted that the order of implanting the PMOS and NMOS devices can be exchanged. The devices are annealed to form silicides on the NMOS and PMOS devices. Dual silicide refers to scenarios where different silicides are formed on both NMOS and PMOS devices.

At 416, the metal gate contacts of the MOS devices are open, for example through etching. Similarly, an insulating layer is made on the sidewall of the created vias. Subsequently, the vias to the source, drain, and/or gate of the MOS devices are filled with a low resistance metal(s). The low resistance metal may comprise titanium, tungsten, molybdenum, ruthenium, cobalt, aluminum, nickel, or a combination thereof.

The method for fabricating a low resistance contact on a semiconductor substrate may further involve chemical-mechanical polishing (CMP) and/or the fabrication of copper dual-damascene (CuDD) interconnects.

### Example 2

This example shows examples for forming N-type silicide. For example, the N-type silicide of Example 1 may be formed by Lanthanide rare earth metals, such as erbium (Er), ytterbium (Yb), dysprosium (Dy), gadolinium (Gd), and scandium (Sc). These metallic elements may be contained in gaseous precursors. Such gaseous precursors, when heated with a mixture of aluminum chloride (AI [symbol] CI [symbol] _3), may be volatilized and transferred in the gas phase.

These metallic elements may be implanted in the N-type region(s) on the semiconductor substrate to form corresponding silicide. The resulting silicide may have an EWF from about 0.4 eV to about 0.2 eV. The annealing temperature for these exemplary metallic elements is less than 500° C., less than 430° C., or preferably less than 400° C.

### Example 3

This example shows examples for forming N-type silicide. For example, the N-type silicide of Example 1 may be formed by hafnium (Hf), zirconium (Zr), and molybdenum (Mo).

Hafnium (Hf), zirconium (Zr), and molybdenum (Mo) compounds of fluorides, oxyfluorides, and chlorides may form volatile precursors. The borohydrides of these metallic elements may be delivered to the ion chamber as a mixture or with a co-flow of H_2 and/or B_2 H_6.

Among these compounds, hafnium tetrachloride (HfCl_4) is solid at standard temperature and pressure. The volatile condition for HfCl_4 is when its vapor pressure (P_vap) reaches one torr at 190° C. The melting temperature is 432° C.

Zirconium tetrafluoride (ZrF_4) is solid at standard temperature and pressure. The volatile condition for ZrF_4 is when its vapor pressure (P_vap) reaches 750 torr at 350° C. The melting temperature is 910° C.

Zirconium borohydride (Zr(BH_4) _4) is solid at standard temperature and pressure. The volatile condition for Zr(BH_4) _4 is when its vapor pressure (P_vap) reaches one torr at 0° C. The melting temperature is 32° C.

Molybdenum chloride (MoCl_5) is solid at standard temperature and pressure. The volatile condition for MoCl_5 is when its vapor pressure (P_vap) reaches 131 torr at 250° C. The melting temperature is 194° C., and the boiling temperature is 268° C.

Molybdenum pentafluoride (MoF_5) is solid at standard temperature and pressure. The volatile condition for MoF_5 is when its vapor pressure (P_vap) reaches 75 torr at −13° C. The melting temperature is 45.7° C., and its sublimation point is at 50° C.

Molybdenum hexafluoride (MoF_6) is liquid at standard temperature and pressure. The volatile condition for MoF_6 is when its vapor pressure (P_vap) reaches 75 torr at 140° C. The melting temperature is 17.5° C., and the boiling temperature is 34° C.

Molybdenum oxytetrafluoride (MoOF_4) is solid at standard temperature and pressure. The volatile condition for MoOF_4 is when its vapor pressure (P_vap) reaches 75 torr at 117° C.

Molybdenum hexacarbonyl (M o(CO)_6) is solid at standard temperature and pressure. The volatile condition for Mo(CO)_6 is when its vapor pressure (P_vap) reaches 75 torr at 109° C. The melting temperature is 150° C., and the boiling temperature is 156° C.

Molybdenum or molybdenum oxide and hafnium or hafnium oxide may be sputtered with fluorinating agents such as F_2 or PF_3, or with chlorinating agents such as Cl_2 or PCI_5. HfF_4 and ZrF_4 are volatile at higher temperatures, so targets may be sputtered or volatilized in or close to the arc chamber with a hot carrier gas (Ar, N_2, He, H_2) to create ions for implantation.

These metallic elements may be implanted in the N-type region(s) on the semiconductor substrate to form corresponding silicide. The resulting silicide may have an EWF from about 0.55 eV to about 0.5 eV. The annealing temperature for these exemplary metallic elements is less than 500° C., less than 430° C., or preferably less than 400° C.

### Example 4

This example shows examples for forming P-type silicide. For example, the P-type silicide of Example 1 may be formed by iridium (Ir), platinum (Pt), osmium (Os), ruthenium (Ru), palladium (Pd), rhenium (Re), and rhodium (Rh). The corresponding precursors may include compounds of these metallic elements, such as fluorides, oxyfluorides, carbonyls, and oxides, in pure forms and their mixtures.

For example, platinum metals, such as iridium (Ir), platinum (Pt), ruthenium (Ru), palladium (Pd), rhodium (Rh), form compounds with PF_3 with varying volatility and stability. Trifluorophosphine metal hydrides with Ru (RuH_2 [symbol] (PF_3) [symbol] _4), Os (OsH_2 [symbol] (PH_3) [symbol] _4), and Ir (IrH [symbol] (PF_3) [symbol] _4) are volatile liquids with excellent thermal stability.

Among these compounds, iridium hexafluoride IrF_6 is solid at standard temperature and pressure. The volatile condition for IrF_6 is when its vapor pressure (P_vap) reaches 750 torr at 54° C. The melting temperature is 44° C., and the boiling temperature is 54° C.

Tetrakis (trifluorophosphine) platinum [symbol] Pt(PF_3) [symbol] _4 is liquid at standard temperature and pressure. The volatile condition for [symbol] Pt(PF_3) [symbol] _4 is when its vapor pressure (P_vap) reaches 68 torr at 20° C. The melting temperature is −15° C., and the boiling temperature is between 86-87° C.

Platinum hexafluoride PtF 6 is solid at standard temperature and pressure. The volatile condition for PtF_6 is when its vapor pressure (P_vap) reaches 140 torr at 25° C. The melting temperature is 61° C., and the boiling temperature is between 68-69° C.

Osmium tetroxide OsO_4 is solid at standard temperature and pressure, which sublimes. The volatile condition for OsO_4 is when its vapor pressure (P_vap) reaches 7 torr at 20° C. The melting temperature is 40° C., and the boiling temperature is 130° C.

Osmium carbonyl [symbol] Os_3 CO [symbol] _12 is solid at standard temperature and pressure, which sublimes. The melting temperature is 224° C.

Osmium pentafluoride OsF_5 is solid at standard temperature and pressure. The volatile condition for OsF_5 is when its vapor pressure (P_vap) reaches 75 torr at 162° C. The melting temperature is 33° C., and the boiling temperature is between 47-46° C.

Osmium hexafluoride OsF_6 is solid at standard temperature and pressure. The volatile condition for OsF_6 is when its vapor pressure (P_vap) reaches 750 torr at 47° C. The melting temperature is between 33-34° C., and the boiling temperature is between 47-48° C.

Ruthenium hexafluoride RuF_6 is solid at standard temperature and pressure. The volatile condition for RuF_6 is when its vapor pressure (P_vap) reaches 70 torr at 60° C. The melting temperature is 54° C., and the boiling temperature is 200° C.

Ruthenium pentafluoride RuF_5 is solid at standard temperature and pressure. The volatile condition for RuF_5 is when its vapor pressure (P_vap) reaches 22 torr at 130° C. The melting temperature is 86.5° C., and the boiling temperature is 227° C.

Ruthenium carbonyl [symbol] Ru(CO) [symbol] _5 is liquid at standard temperature and pressure. The volatile condition for [symbol] Ru(CO) [symbol] _5 is when its vapor pressure (P_vap) reaches 50 torr at 18° C. The melting temperature is −16° C.

Ruthenium tetroxide RuO_4 is solid at standard temperature and pressure. The volatile condition for RuO_4 is when its vapor pressure (P_vap) reaches 10 torr at 25° C. The melting temperature is 25° C., and the boiling temperature is between 40-130° C.

Rhenium pentafluoride oxide ReOF_5 is solid at standard temperature and pressure. The volatile condition for ReOF_5 is when its vapor pressure (P_vap) reaches 75 torr at 14° C.

Rhenium pentafluoride ReF_5 is solid at standard temperature and pressure. The volatile condition for ReF_5 is when its vapor pressure (P_vap) reaches 7.5 torr at 59° C. The melting temperature is 48° C., and the boiling temperature is 221° C.

Rhenium hexafluoride ReF 6 is liquid at standard temperature and pressure. The volatile condition for ReF_6 is when its vapor pressure (P_vap) reaches 750 torr at 34° C. The melting temperature is between 18-19° C., and the boiling temperature is between 33-34° C.

Rhenium heptafluoride ReF_7 is solid at standard temperature and pressure. The volatile condition for ReF_7 is when its vapor pressure (P_vap) reaches 100 torr at 22° C. The melting temperature is between 48-49° C., and the boiling temperature is between 73-74° C.

These metallic elements may be implanted in the P-type region(s) on the semiconductor substrate to form corresponding silicide. The resulting silicide may have an EWF from about 0.7 eV to about 0.95 eV. The annealing temperature for these exemplary metallic elements is less than 500° C., less than 430° C., or preferably less than 400° C.

All references, including publications, patent applications, and patents, cited herein are hereby incorporated by reference to the same extent as if each reference were individually and specifically indicated to be incorporated by reference and were set forth in its entirety herein.

### EMBODIMENTS

Aspects, including embodiments, of the disclosure described herein may be beneficial alone or in combination, with one or more other aspects or embodiments. Without limiting the foregoing description, certain non-limiting embodiments of the disclosure numbered 1-28 are provided below. As will be apparent to those of skill in the art upon reading this disclosure, each of the individually numbered embodiments may be used or combined with any of the preceding or following individually numbered embodiments. This is intended to provide support for all such combinations of embodiments and is not limited to combinations of embodiments explicitly provided below:

(1) Embodiment (1) presents a method for fabricating a low resistance contact on a semiconductor substrate comprising a metal oxide semiconductor (M OS) device, the method comprising:
(i) fabricating a via to a source or drain region of the M OS device, wherein the source or drain region comprises silicon, to expose the source or drain region;
(ii) providing an insulating layer along a sidewall of the via while maintaining or reestablishing the exposed source or drain region;
(iii) using ion implantation to implant a metallic element into the exposed source or drain region of the semiconductor substrate through the via to form an implanted layer, wherein the metallic element is erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof;
(iv) annealing the implanted layer to form a silicide layer comprising silicon and the metallic element on the source or drain region of the MOS device; and
(v) depositing a low resistance metal in the via to form the low resistance contact on the semiconductor substrate comprising the MOS device.

(2) Embodiment (2) presents the method of embodiment (1), wherein annealing the implanted layer comprises exposing the semiconductor substrate to a temperature of 430° C. or lower.

(3) Embodiment (3) presents the method of embodiment (1), wherein annealing the implanted layer comprises exposing the semiconductor substrate to a temperature of 430° C. to 450° C.

(4) Embodiment (4) presents the method of embodiment (1), wherein annealing the implanted layer comprises exposing the semiconductor substrate to a temperature of 450° C. to 500° C.

(5) Embodiment (5) presents the method of any one of embodiments (1)-(4), wherein the method further comprises a step of pre-amorphization implantation of the source or drain region with silicon (Si) or germanium (Ge) prior to using ion implantation to implant a metallic element into the exposed source or drain region of the semiconductor substrate.

(6) Embodiment (6) presents the method of any one of embodiments (1)-(5), wherein the method comprises fabricating a via to a source or drain region of an N-channel metal-oxide semiconductor, wherein the source or drain region comprises silicon, to expose the source or drain region.

(7) Embodiment (7) presents the method of embodiment (6), wherein the metallic element used for ion implantation of the source or drain region of the N-channel metal-oxide semiconductor is erbium (Er), ytterbium (Yb), dysprosium (Dy), gadolinium (Gd), scandium (Sc), hafnium (Hf), zirconium (Zr), molybdenum (Mo), or a combination thereof and the silicide layer of the N-channel metal-oxide semiconductor comprises silicon and erbium (Er), ytterbium (Yb), dysprosium (Dy), gadolinium (Gd), scandium (Sc), hafnium (Hf), zirconium (Zr), molybdenum (Mo), or a combination thereof.

(8) Embodiment (8) presents the method of embodiment (7), wherein the silicide layer of the N-channel metal-oxide semiconductor has a work function from about 0.55 eV to about 0.2 eV.

(9) Embodiment (9) presents the method of embodiment (7) or embodiment (8), wherein the metallic element is erbium (Er), ytterbium (Yb), dysprosium (Dy), or gadolinium (Gd) and the ion implantation utilizes a volatile mixture of aluminum chloride and erbium (Er) chloride, ytterbium (Yb) chloride, dysprosium (Dy) chloride, or gadolinium (Gd) chloride as a source to implant the metallic element.

(10) Embodiment (10) presents the method of embodiment (7) or embodiment (8), wherein the metallic element is hafnium (Hf), zirconium (Zr), or molybdenum (Mo) and the ion implantation utilizes hafnium tetrachloride, zirconium borohydride, zirconium tetrafluoride, molybdenum chloride, molybdenum pentafluoride, molybdenum hexafluoride, molybdenum oxytetrafluoride, or molybdenum hexacarbonyl as a source to implant the metallic element.

(11) Embodiment (11) presents the method of any one of embodiments (1)-(10), wherein the method comprises fabricating a via to a source or drain region of a P-channel metal-oxide semiconductor, wherein the source or drain region comprises silicon, to expose the source or drain region.

(12) Embodiment (12) presents the method of embodiment (11), wherein the metallic element used for ion implantation of the source or drain region of the P-channel metal-oxide semiconductor is iridium (Ir), platinum (Pt), osmium (Os), ruthenium (Ru), palladium (Pd), rhenium (Re), rhodium (Rh), or a combination thereof and the silicide layer of the P-channel metal-oxide semiconductor comprises silicon and iridium (Ir), platinum (Pt), osmium (Os), ruthenium (Ru), palladium (Pd), rhenium (Re), rhodium (Rh), or a combination thereof.

(13) Embodiment (13) presents the method of embodiment (12), wherein the silicide layer of the P-channel metal-oxide semiconductor has a work function from about 0.7 eV to about 0.95 eV.

(14) Embodiment (14) presents the method of embodiment (12) or embodiment (13), wherein the metallic element is iridium (Ir), platinum (Pt), osmium (Os), ruthenium (Ru), or rhenium (Re) and the ion implantation utilizes iridium hexafluoride, tetrakis (trifluorophosphine) platinum, osmium tetroxide, osmium carbonyl, osmium pentafluoride, osmium hexafluoride, ruthenium hexafluoride, ruthenium pentafluoride, ruthenium carbonyl, ruthenium tetroxide, rhenium pentafluoride oxide, rhenium pentafluoride, rhenium hexafluoride, or rhenium heptafluoride as a source to implant the metallic element.

(15) Embodiment (15) presents the method of any one of embodiments (9)-(14), wherein the source to implant the metallic element is generated by exposing the metallic element or an oxide thereof to a fluorinating vapor or a chlorinating agent.

(16) Embodiment (16) presents the method of any one of embodiments (1)-(15), wherein the method comprises fabricating vias to source and drain regions comprising silicon of an N-channel metal-oxide semiconductor to expose the source and drain regions and fabricating vias to source and drain regions comprising silicon of a P-channel metal-oxide semiconductor to expose the source and drain regions.

(17) Embodiment (17) presents the method of embodiment (16), wherein the method further comprises masking the source and drain regions of the P-channel metal-oxide semiconductor and selectively implanting erbium (Er), ytterbium (Y b), dysprosium (Dy), gadolinium (Gd), scandium (Sc), hafnium (Hf), zirconium (Zr), molybdenum (Mo), or a combination thereof into the exposed source and drain regions of the N-channel metal-oxide semiconductor.

(18) Embodiment (18) presents the method of any one of embodiment (16), or embodiment (17), wherein the method further comprises masking the source and drain regions of the N-channel metal-oxide semiconductor and selectively implanting iridium (Ir), platinum (Pt), osmium (Os), ruthenium (Ru), palladium (Pd), rhenium (Re), rhodium (Rh), or a combination thereof into the exposed source and drain regions of the P-channel metal-oxide semiconductor.

(19) Embodiment (19) presents the method of any one of embodiments (16)-(18), wherein the method comprises forming a dual silicide where the N-channel metal-oxide semiconductor comprises a first silicide layer comprising silicon and erbium (Er), ytterbium (Yb), dysprosium (Dy), gadolinium (Gd), scandium (Sc), hafnium (Hf), zirconium (Zr), molybdenum (Mo), or a combination thereof on the source and drain regions of the N-channel metal-oxide semiconductor and the P-channel metal-oxide semiconductor comprises a second silicide layer comprising silicon and iridium (Ir), platinum (Pt), osmium (Os), ruthenium (Ru), palladium (Pd), rhenium (Re), rhodium (Rh), or a combination thereof on the source and drain regions of the P-channel metal-oxide semiconductor.

(20) Embodiment (20) presents the method of any one of embodiments (1)-(19), wherein the low resistance contact is fabricated on a backside power delivery network of the semiconductor substrate.

(21) E embodiment (21) presents the method of any one of embodiments (1)-(19), wherein the low resistance contact is fabricated on a frontside power delivery network of the semiconductor substrate.

(22) Embodiment (22) presents the method of any one of embodiments (1)-(21), wherein the insulating layer comprises silicon oxide.

(23) Embodiment (23) presents the method of any one of embodiments (1)-(22), wherein the low resistance metal comprises titanium, tungsten, molybdenum, ruthenium, cobalt, aluminum, nickel, or a combination thereof.

(24) Embodiment (24) presents the method of any one of embodiments (1)-(23), wherein the method further comprises chemical-mechanical polishing (CMP) of the low resistance metal to planarize the low resistance metal.

(25) Embodiment (25) presents the method of any one of embodiments (1)-(24), the method further comprising: growing epitaxial silicon in the source or drain region of the semiconductor substrate prior to the ion implantation of the metallic element, wherein the step of using ion implantation to implant a metallic element into the exposed source or drain region of the semiconductor substrate comprises using ion implantation to implant a metallic element into the epitaxial silicon grown in the source or drain region of the semiconductor substrate to form an implanted layer comprising the epitaxial silicon and the implanted metallic element.

(26) Embodiment (26) presents a device comprising a low resistance contact fabricated by the method of any one of embodiments (1)-(25).

(27) Embodiment (27) presents a semiconductor device comprising:
(a) a metal oxide semiconductor (M OS) comprising source and drain regions;
(b) vias extending to the source and drain regions of the MOS, wherein the vias have sidewalls covered by an insulating layer;
(c) silicide layers comprising silicon and a metallic element selected from erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof on the source and drain regions of the MOS device; and
(d) a low resistance metal on the silicide layers and filling in the vias.

(28) Embodiment (28) presents the semiconductor device of embodiment (27), further comprising:
(i) an N-channel metal-oxide semiconductor comprising source and drain regions; a first set of vias extending to the source and drain regions of the N-channel metal-oxide semiconductor, wherein the first set of vias have sidewalls covered by a first insulating layer;
   a first set of silicide layers comprising silicon and a metallic element selected from erbium (Er), ytterbium (Y b), dysprosium (Dy), gadolinium (Gd), scandium (Sc), hafnium (Hf), zirconium (Zr), molybdenum (Mo), or a combination thereof on the source and drain regions of the N-channel metal-oxide semiconductor; and a first low resistance metal on the first set of silicide layers and filling in the first set of vias; and
(ii) a P-channel metal-oxide semiconductor comprising source and drain regions; a second set of vias extending to a surface of the source and drain regions of the P-channel metal-oxide semiconductor, wherein the second set of vias have sidewalls covered by a second insulating layer;
   a second set of silicide layers comprising silicon and a metallic element selected from iridium (Ir), platinum (Pt), osmium (Os), ruthenium (Ru), palladium (Pd), rhenium (Re), rhodium (Rh), or a combination thereof on the source and drain regions of the P-channel metal-oxide semiconductor; and
   a second low resistance metal on the second set of silicide layers and filling in the second set of vias.

The use of the terms “a” and “an” and “the” and “at least one” and similar referents in the context of describing the disclosure (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosure and does not pose a limitation on the scope of the disclosure unless otherwise claimed. No language in the specification should be construed as indicating any non-claimed element as essential to the practice of the disclosure.

Preferred embodiments of this disclosure are described herein, including the best mode known to the inventors for carrying out the disclosure. Variations of those preferred embodiments may become apparent to those of ordinary skill in the art upon reading the foregoing description. The inventors expect skilled artisans to employ such variations as appropriate, and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

1. A method for fabricating a low resistance contact on a semiconductor substrate comprising a metal oxide semiconductor (MOS) device, the method comprising:
fabricating a via to a source or drain region of the MOS device, wherein the source or drain region comprises silicon, to expose the source or drain region;
forming an insulating layer along a sidewall of the via while maintaining or reestablishing the exposed source or drain region;
using ion implantation to implant a metallic element into the exposed source or drain region of the semiconductor substrate through the via to form an implanted layer, wherein the metallic element is erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof;
annealing the implanted layer to form a silicide layer comprising silicon and the metallic element on the source or drain region of the MOS device; and
depositing a low resistance metal in the via to form the low resistance contact on the semiconductor substrate comprising the M OS device.

2. The method of claim 1, wherein the method further comprises a step of pre-amorphization implantation of the source or drain region with silicon (Si) or germanium (Ge) prior to using ion implantation to implant a metallic element into the exposed source or drain region of the semiconductor substrate.

3. The method of claim 1, wherein the method comprises fabricating a via to a source or drain region of an N-channel metal-oxide semiconductor, wherein the source or drain region comprises silicon, to expose the source or drain region.

4. The method of claim 3, wherein the metallic element used for ion implantation of the source or drain region of the N-channel metal-oxide semiconductor is erbium (Er), ytterbium (Yb), dysprosium (Dy), gadolinium (Gd), scandium (Sc), hafnium (Hf), zirconium (Zr), molybdenum (Mo), or a combination thereof and the silicide layer of the N-channel metal-oxide semiconductor comprises silicon and erbium (Er), ytterbium (Yb), dysprosium (Dy), gadolinium (Gd), scandium (Sc), hafnium (Hf), zirconium (Zr), molybdenum (Mo), or a combination thereof.

5. The method of claim 4, wherein the silicide layer of the N-channel metal-oxide semiconductor has a work function from about 0.55 eV to about 0.2 eV.

6. The method of claim 5, wherein the metallic element is erbium (Er), ytterbium (Yb), dysprosium (Dy), or gadolinium (Gd) and the ion implantation utilizes a volatile mixture of aluminum chloride and erbium (Er) chloride, ytterbium (Yb) chloride, dysprosium (Dy) chloride, or gadolinium (Gd) chloride as a source to implant the metallic element.

7. The method of claim 5, wherein the metallic element is hafnium (Hf), zirconium (Zr), or molybdenum (Mo) and the ion implantation utilizes hafnium tetrachloride, zirconium borohydride, zirconium tetrafluoride, molybdenum chloride, molybdenum pentafluoride, molybdenum hexafluoride, molybdenum oxytetrafluoride, or molybdenum hexacarbonyl as a source to implant the metallic element.

8. The method of claim 1, wherein the method comprises fabricating a via to a source or drain region of a P-channel metal-oxide semiconductor, wherein the source or drain region comprises silicon, to expose the source or drain region.

9. The method of claim 8, wherein the silicide layer of the P-channel metal-oxide semiconductor has a work function from about 0.7 eV to about 0.95 eV.

10. The method of claim 8, wherein the metallic element used for ion implantation of the source or drain region of the P-channel metal-oxide semiconductor is iridium (Ir), platinum (Pt), osmium (Os), ruthenium (Ru), palladium (Pd), rhenium (Re), rhodium (Rh), or a combination thereof and the silicide layer of the P-channel metal-oxide semiconductor comprises silicon and iridium (Ir), platinum (Pt), osmium (Os), ruthenium (Ru), palladium (Pd), rhenium (Re), rhodium (Rh), or a combination thereof.

11. The method of claim 1, wherein the method comprises fabricating vias to source and drain regions comprising silicon of an N-channel metal-oxide semiconductor to expose the source and drain regions and fabricating vias to source and drain regions comprising silicon of a P-channel metal-oxide semiconductor to expose the source and drain regions.

12. The method of claim 11, wherein the method comprises forming a dual silicide where the N-channel metal-oxide semiconductor comprises a first silicide layer comprising silicon and erbium (Er), ytterbium (Yb), dysprosium (Dy), gadolinium (Gd), scandium (Sc), hafnium (Hf), zirconium (Zr), molybdenum (Mo), or a combination thereof on the source and drain regions of the N-channel metal-oxide semiconductor and the P-channel metal-oxide semiconductor comprises a second silicide layer comprising silicon and iridium (Ir), platinum (Pt), osmium (Os), ruthenium (Ru), palladium (Pd), rhenium (Re), rhodium (Rh), or a combination thereof on the source and drain regions of the P-channel metal-oxide semiconductor.

13. The method of claim 1, wherein the low resistance contact is fabricated on a backside power delivery network of the semiconductor substrate.

14. The method of claim 1, wherein the low resistance contact is fabricated on a frontside power delivery network of the semiconductor substrate.

15. The method of claim 1, wherein the insulating layer comprises silicon oxide.

16. The method of claim 1, wherein the low resistance metal comprises titanium, tungsten, molybdenum, ruthenium, cobalt, nickel, or a combination thereof.

17. The method of claim 1, further comprising:
growing epitaxial silicon in the source or drain region of the semiconductor substrate prior to the ion implantation of the metallic element, wherein the step of using ion implantation to implant a metallic element into the exposed source or drain region of the semiconductor substrate comprises using ion implantation to implant a metallic element into the epitaxial silicon grown in the source or drain region of the semiconductor substrate to form an implanted layer comprising the epitaxial silicon and the implanted metallic element.

18. A semiconductor device, comprising:
a metal oxide semiconductor (MOS) comprising source and drain regions;
vias extending to the source and drain regions of the MOS, wherein the vias have sidewalls covered by an insulating layer;
silicide layers comprising silicon and a metallic element selected from erbium (Er), ytterbium (Yb), dysprosium (Dy), gadolinium (Gd), scandium (Sc), hafnium (Hf), zirconium (Zr), molybdenum (Mo), iridium (Ir), platinum (Pt), osmium (Os), ruthenium (Ru), palladium (Pd), rhenium (Re), rhodium (Rh), or a combination thereof on the source and drain regions of the MOS device; and
a low resistance metal on the silicide layers and filling in the vias.

19. The semiconductor device of claim 18, wherein semiconductor device comprises:
(i) an N-channel metal-oxide semiconductor comprising source and drain regions;
a first set of vias extending to the source and drain regions of the N-channel metal-oxide semiconductor, wherein the first set of vias have sidewalls covered by a first insulating layer;
a first set of silicide layers comprising silicon and a metallic element selected from erbium (Er), ytterbium (Yb), dysprosium (Dy), gadolinium (Gd), scandium (Sc), hafnium (Hf), zirconium (Zr), molybdenum (Mo), or a combination thereof on the source and drain regions of the N-channel metal-oxide semiconductor; and
a first low resistance metal on the first set of silicide layers and filling in the first set of vias, and
(ii) a P-channel metal-oxide semiconductor comprising source and drain regions;
a second set of vias extending to a surface of the source and drain regions of the P-channel metal-oxide semiconductor, wherein the second set of vias have sidewalls covered by a second insulating layer;
a second set of silicide layers comprising silicon and a metallic element selected from iridium (Ir), platinum (Pt), osmium (Os), ruthenium (Ru), palladium (Pd), rhenium (Re), rhodium (Rh), or a combination thereof on the source and drain regions of the P-channel metal-oxide semiconductor; and
a second low resistance metal on the second set of silicide layers and filling in the second set of vias.
